(19) United States
(12) Patent Application Publication
(10) Pub. No.: US 2008/0056315 A1
(43) Pub. Date: Mar. 6, 2008

(54) Semiconductor laser device

(75) Inventor: Kenichi Kurita, Hiroshima (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/892,866

(22) Filed: Aug. 28, 2007

(30) Foreign Application Priority Data
Aug. 31, 2006 (JP) P2006-235078

(51) Int. Cl. H01S 5/022

(52) U.S. Cl. 372/36

(57) ABSTRACT

There is provided a semiconductor laser device which has a semiconductor laser element of a large cavity length and in which an outside shape and outside dimensions of a package are generally identical to those of the conventional one. A mounting portion 10 of a first lead 2 for the semiconductor laser element 1 has a portion that overlaps a second leads 3 in a direction perpendicular to an optical axis direction of laser light emitted from the semiconductor laser element 1, and the first lead 2 and the second leads 3 are integrally retained by a resin member 5 so that the first lead 2 and the second leads 3 are not electrically connected to each other.

This nonprovisional application claims priority under 35 U.S.C. §119(a) on Patent Application No. 2006-235078 filed in Japan on Aug. 31, 2006, the entire contents of which are hereby incorporated by reference.

### BACKGROUND OF THE INVENTION

The present invention relates to semiconductor laser devices and, in particular, to a semiconductor laser device suitable for use as a light source for applying light to an optical disk.

Conventionally, there has been a semiconductor laser device described in JP 2005-311147 A.

FIG. 12 is a plan view of the semiconductor laser device.

The semiconductor laser device includes a semiconductor laser element 101, a first lead 102, three second leads 103 for signal output use, and a resin portion 107. The first lead 102 has a mounting portion 102a and a lead portion 102b, and the semiconductor laser element 101 is mounted on the mounting portion 102b via a submount member 108. Moreover, the resin portion 107 is made of an insulative resin material such as epoxy resin and integrally retains the three second leads 103.

In the semiconductor laser device, the semiconductor laser element 101 is supplied with power by applying a voltage between an upper surface, which is opposite from the submount member 108 side, of the semiconductor laser element 101 and the submount member 108. By thus supplying the semiconductor laser element 101 with power, laser light is emitted upward in the sheet plane of FIG. 12 from the semiconductor laser element 101.

As shown in FIG. 12, in the conventional semiconductor laser device, an edge of the mounting portion 102a of the first lead 102 on the lead portion 102b side is located closer to the semiconductor laser element 101 than the ends of the second leads 103 on the semiconductor laser element 101 side in the optical axis direction of the laser light.

In this case, a laser chip cavity length has recently been increased in accordance with an increase in the power of the semiconductor laser element. However, since the edge of the mounting portion 102a on the lead portion 102b side is located closer to the semiconductor laser element 101 than the ends of the second leads 103 on the semiconductor laser element 101 side in the optical axis direction of the laser light in the conventional semiconductor laser device, there is a problem that only a semiconductor laser element 101 of which the laser chip cavity length is up to 1500 μm can be mounted on the semiconductor laser device.

### SUMMARY OF THE INVENTION

An object of the present invention is to provide a semiconductor laser device that has a semiconductor laser element of a large cavity length and is able to make the outside shape and the outside dimensions of the package generally identical to those of the conventional one.

In order to solve the above problem, the semiconductor laser device of the present invention comprises:

a semiconductor laser element;

a first lead having a mounting portion on which the semiconductor laser element is mounted via a submount member and a lead portion that extends in connection to the mounting portion;

at least one second lead; and

a retention member that integrally retains the first lead and the second lead in a state in which the first lead and the second lead are not electrically connected with each other and is made of an insulating material, wherein

the mounting portion has a portion that overlaps the second lead when viewed in plan in a direction perpendicular to an optical axis direction of laser light emitted from the semiconductor laser element.

It is noted that the mounting portion means a portion of the first lead on which the semiconductor laser element can be mounted.

According to the present invention, the mounting portion has the portion that overlaps the second leads when viewed in plan in the direction perpendicular to the optical axis direction of laser light emitted from the semiconductor laser element. Therefore, in comparison with the conventional construction, i.e., the construction in which an edge of a mounting portion on a second lead side is located closer to a semiconductor laser element than ends of second leads on the semiconductor laser element side in an optical axis direction of laser light, the dimension in the optical axis direction of the semiconductor laser element of the present invention can remarkably be increased. Then, the cavity length of the semiconductor laser element can be made greater than 1500 μm, and the load of laser oscillation can be reduced, allowing the output of laser light to be increased.

In one embodiment, a mounting surface in the mounting portion for the semiconductor laser element comprises:

a first portion of a generally rectangular shape; and

a second portion that connects to the first portion in the optical axis direction and whose maximum dimension in a direction perpendicular to the optical axis direction is smaller than a dimension in a widthwise direction of the first portion, and

the second portion has a portion that overlaps the second lead when viewed in plan from the direction perpendicular to the optical axis direction and has a portion put in contact with the submount member.

In one embodiment, the lead portion of the first lead has a first portion and a second portion that extends generally parallel to the first portion.

In one embodiment, each of the first lead and the second lead penetrates the retention member, and

the portion that penetrates the retention member of at least one of the first lead and the second leads has a bent portion.

In one embodiment, the lead portion of the first lead has a first surface portion that connects to a mounting surface of the mounting portion on which the semiconductor laser element is mounted and that has a normal line which is not parallel to a normal line of the mounting surface.

In one embodiment, a surface of the lead portion of the first lead on the semiconductor laser element side has a second surface portion located in a plane identical to a surface of the second lead on the semiconductor laser element side.

In one embodiment, the first surface portion is covered with the retention member.

In one embodiment, the maximum dimension of the second portion in the direction perpendicular to the optical axis direction is not smaller than 800 μm.

One embodiment comprises a lid portion that is placed spaced apart from the mounting portion in a normal direction of a mounting surface on which the semiconductor laser element is mounted in the mounting portion and is made of an insulating material.

In one embodiment, a portion of projection of the semiconductor laser element in a surface opposite from the semiconductor laser element side of the mounting portion with respect to a normal direction of the surface opposite from the semiconductor laser element side of the mounting portion is exposed, and

a heat radiation member having a thermal conductivity of not smaller than a prescribed thermal conductivity is put in contact with the portion of projection.

Moreover, according to another aspect, a semiconductor laser device of the present invention comprises:

a semiconductor laser element;

a first lead having a mounting portion on which the semiconductor laser element is mounted via a submount member and a lead portion that extends in connection to the mounting portion;

at least one second lead; and

a retention member that integrally retains the first lead and the second lead in a mutually insulated state and is made of an insulating material, wherein

a part of the second lead is located at least on one side in a direction perpendicular to an optical axis direction of laser light emitted from the semiconductor laser element with regard to a part of the mounting portion that connects to the lead portion of the first lead.

In one embodiment, the mounting portion comprises:

a first portion of a generally rectangular shape; and

a second portion that connects to the first portion in the optical axis direction and whose maximum dimension in the direction perpendicular to the optical axis direction is smaller than a dimension in a widthwise direction of the first portion, wherein

a part of the second lead is located at least on one side of the second portion, and

the second portion has a portion put in contact with the submount member.

According to the semiconductor laser device of the present invention, the mounting portion has the portion that overlaps the second leads in the direction perpendicular to the optical axis direction of laser light emitted from the semiconductor laser element. Therefore, the dimension in the optical axis direction of the semiconductor laser element can remarkably be increased, and the cavity length of the semiconductor laser element can be made greater than 1500 μm. Therefore, the load of laser oscillation can be reduced, and the output of laser light can be increased.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a plan view of a semiconductor laser device of a first embodiment of the present invention.

FIG. 2 is a plan view of only first and second leads 2 and 3, which are frame portions of the semiconductor laser device of the first embodiment.

FIG. 3 is a view showing portions other than a semiconductor laser element and a submount member in FIG. 1.

FIG. 4 is a sectional view taken along a line B-B of FIG. 3.

FIG. 5 is a sectional view taken along a line C-C of FIG. 3.

FIG. 6 is a side view when the state of FIG. 3 is viewed from the direction indicated by arrow D in FIG. 3.

FIG. 7 is a front view when the state of FIG. 3 is viewed from the direction indicated by arrow E in FIG. 3.

FIG. 8 is a plan view of a semiconductor laser device of a second embodiment of the present invention.

FIG. 9 is a plan view of a semiconductor laser device of a third embodiment of the present invention.

FIG. 10 is a side view when the state of FIG. 9 is viewed from a direction indicated by arrow G in FIG. 9.

FIG. 11 is a front view when the state of FIG. 9 is viewed from a direction indicated by arrow H in FIG. 9.

FIG. 12 is a plan view of a conventional semiconductor laser device.

### DETAILED DESCRIPTION OF THE INVENTION

The present invention will be described in detail below by the embodiments shown in the drawings.

### The First Embodiment

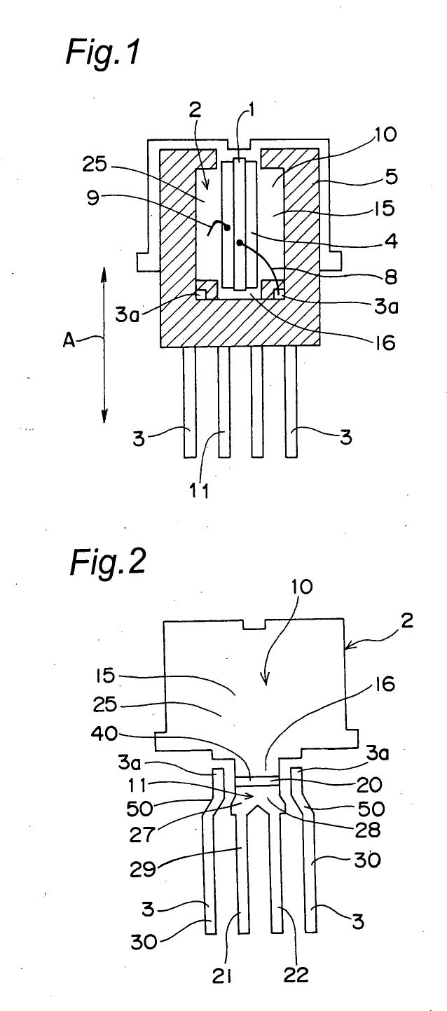

FIG. 1 is a plan view of the semiconductor laser device of the first embodiment of the present invention.

As shown in FIG. 1, the semiconductor laser device includes a semiconductor laser element 1, a first lead 2, second leads 3, a submount member 4 and a resin member 5 as a retention member.

The cavity length of the semiconductor laser element 1 is greater than the cavity length of the semiconductor laser element owned by the conventional semiconductor laser device of which the shape and the dimension of the package are of the same degrees and has, in concrete, a value greater than 1500 μm. The first lead 2 and the second leads 3 are made of a metal material and have conductivity. In concrete, the first lead 2 and the second leads 3 are formed by plating a copper alloy with silver in the first embodiment. It is needless to say that another metal of, for example, gold plating may be used for the plating.

The first lead 2 has a mounting portion 10 and a lead portion 11. The semiconductor laser element 1 is mounted on the mounting portion 10 via the submount member 4. The resin member 5 is made of a nonconductive resin as one example of the insulating material. In this case, there are, for example, LCP (liquid crystal polymer), PPS (polyphenylene sulfide), PPA (polyphthalamide) and so on as the nonconductive resin. The resin member 5 integrally retains the first lead 2 and the two second leads 3 in a state in which the first lead 2 is not electrically connected to the second leads 3 (in an electrically nonconducting state) and integrally retains the two second leads 3 in a state in which the two second leads 3 are not mutually electrically continued. In the present embodiment, a bonding strength between the resin member 5 and the plate-shaped mounting portion 10 on which the semiconductor laser element 1 is mounted can be secured by only the first lead 1.

In FIG. 1, a mounting surface 25 of the mounting portion 10 on which the semiconductor laser element 1 is mounted is surrounded by the resin member 5 excluding one side in the laser light emission direction of the semiconductor laser element 1. The mounting surface 25 of the mounting portion 10 on which the semiconductor laser element 1 is mounted has a first portion 15 of a generally rectangular shape and a second portion 16. The longitudinal direction of the first portion 15 generally coincides with the optical axis direction (indicated by arrow A in FIG. 1) of laser light emitted from the semiconductor laser element 1. The second portion 16 connects in the optical axis direction to a generally center portion in the widthwise direction of one end in the lengthwise direction of the first portion 15. The first portion 15 has a width greater than the maximum width (set not smaller than 800 μm in the first embodiment) in a direction perpendicular to the optical axis direction A of the second portion 16.

The semiconductor laser element 1 is mounted over the first portion 15 and the second portion 16 of the mounting surface 25. That is, each of the first portion 15 and the second portion 16 has a portion on which the semiconductor laser element 1 is partially mounted via the submount member 4.

In the plan views shown in FIGS. 1 and 2, the second portion 16 has a portion that overlaps one end portions 3a, 3a of the second leads 3 in the direction perpendicular to the optical axis direction A. That is, with regard to the portion of the mounting surface 25 of the mounting portion 10 having the second portion 16, the one end portions 3a of the second leads 3 are located on both sides in the direction perpendicular to the optical axis direction of laser light emitted from the semiconductor laser element 1. As shown in FIG. 1, the second portion 16 and one end portions 3a of the second leads 3 are spaced apart by a portion having an L-figured shape of the resin member 5 in the plan view of FIG. 1. The first lead 2 and the second leads 3 penetrate the resin member 5.

In FIG. 1, the reference numerals 8 and 9 denote metal wires. The metal wire 8 electrically connects the upper surface of the semiconductor laser element 1 with one second lead 3, and the metal wire 9 electrically connects the submount member 4 with the first lead 2. By applying a voltage between the first lead 2 and the one second lead 3, the semiconductor laser element 1 is driven.

FIG. 2 is a plan view of only the first and second leads 2 and 3, which are the frame portions of the semiconductor laser device.

The lead portion 11 of the first lead 2 has a bent portion 20 that connects to the mounting portion 10 in the optical axis direction and a bifurcated portion 27 that connects to the bent portion 20 in the optical axis direction. The bifurcated portion 27 has a base portion 28 that connects to the bent portion 20 in the optical axis direction, a first portion 21 that projects from the base portion 28, and a second portion 22 that projects from the base portion 28 and extends generally parallel to the first portion 21. A surface 40 of the bent portion 20 of the lead portion 11 of the first lead 2 is bent at an acute angle (>0°) on the front side regarding the sheet plane of FIG. 2 with respect to the mounting surface 25 of the mounting portion 10 on the semiconductor laser element 1 side. Moreover, a surface 29 of the bifurcated portion 27 of the lead portion 11 of the first lead 2 is generally parallel to the mounting surface 25. Moreover, the surface 29 of the bifurcated portion 27 is located in a plane identical to the surface 30 of the second leads 3. Moreover, each of the two second leads 3 extends to the length of the first portion 15 of the mounting surface 25 and has a bent portion 50 bent in the widthwise direction of the first portion 15 of the mounting surface 25. The first lead 2 and the second leads 3 have the bent portions 20 and 50, respectively, and have key-like shapes as shown in FIGS. 2 and 4.

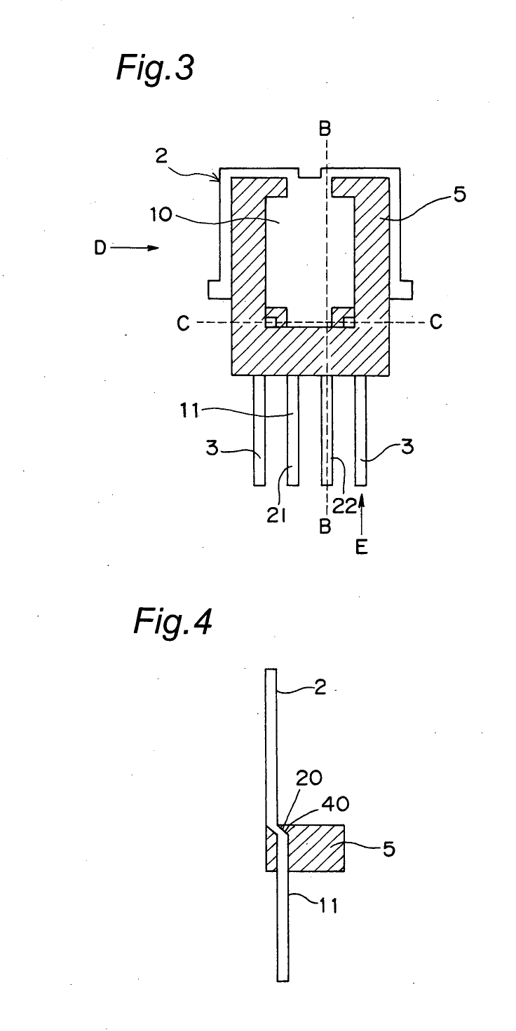

FIG. 3 is a view showing portions other than the semiconductor laser element 1 and the submount member 4 in FIG. 1. As shown in FIGS. 2 and 3, the bent portion 20 of the first lead 2 and the bent portions 50 of the second leads 3 are covered with the resin member 5.

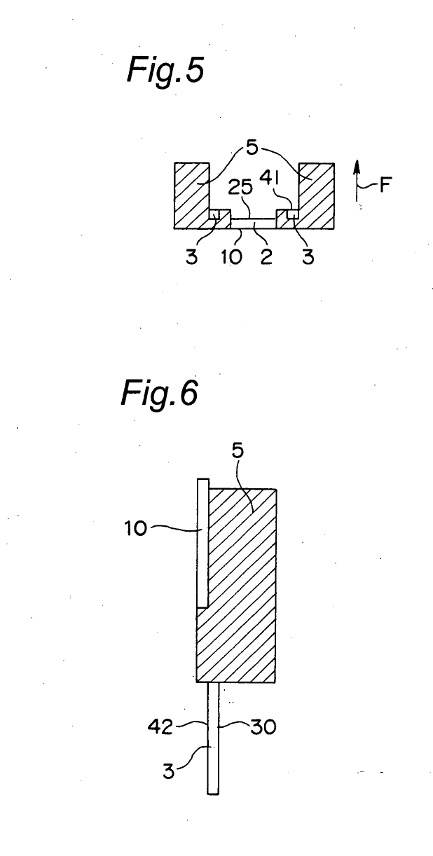

FIG. 4 is a sectional view taken along the line B-B of FIG. 3. FIG. 5 is a sectional view taken along the line C-C of FIG. 3.

As shown in FIG. 4, the first lead 2 penetrates the resin member 5, and the portion of the first lead 2 penetrating the resin member 5 has the bent portion 20. That is, the surface 40 of the bent portion 20 on the semiconductor laser element side is covered with the resin member 5. The surface 40 of the bent portion 20 on the semiconductor laser element side constitutes a first surface portion.

Moreover, as shown in FIG. 5, the mounting portion 10 and the second leads 3 are spaced apart by part of the resin member 5. The mounting surface 25 and exposed surfaces 41 of the second leads 3 on the side where the leads 3 are exposed from the resin member 5 are generally parallel to each other. Moreover, the exposed surfaces 41 are located closer to the semiconductor laser element side in the normal direction (indicated by arrow F) of the mounting surface 25 than the mounting surface 25.

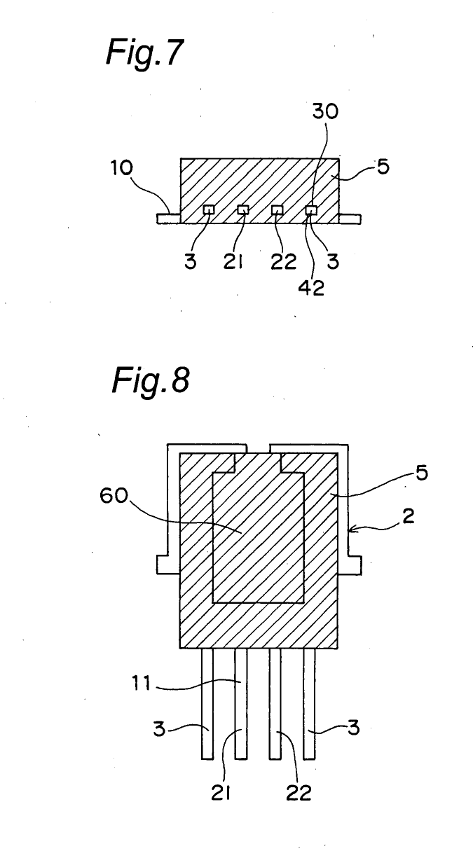

FIG. 6 is a side view when the state of FIG. 3 is viewed from the direction indicated by arrow D in FIG. 3, and FIG. 7 is a front view when the state of FIG. 3 is viewed from the direction indicated by arrow E in FIG. 3.

In the side view shown in FIG. 6, the lead portion 11 of the first lead 2 is hidden by the second leads 3. Moreover, as shown in FIG. 7, surfaces 30 of the second leads 3 on the semiconductor laser element side are in a plane identical to the surfaces 50 of the first and second portions 21, 22 on the semiconductor laser element 1 side, and surfaces 42 of the second leads 3 on the side opposite from the semiconductor laser element 1 are in a plane identical to the surfaces of the first and second portions 21, 22 on the side opposite from the semiconductor laser element 1. With this arrangement, the package of the first embodiment of the invention is made to have an outside shape and outside dimensions generally identical to those of the conventional package. In concrete, for example, the dimension in the widthwise direction of the semiconductor laser device is 1200 μm.

The bifurcated portion 27 of the lead portion 11 of the first lead 2 is located in a plane identical to the surfaces of the second leads 3 on the semiconductor laser element 1 side. The surface of the bifurcated portion 27 of the lead portion 11 on the semiconductor laser element 1 side constitutes a second surface portion.

According to the semiconductor laser device of the first embodiment, the mounting portion 10 has the portion that overlaps the second leads 3 in the direction perpendicular to the optical axis direction of laser light emitted from the semiconductor laser element 1 in the plan views of FIGS. 1 and 2. Therefore, in comparison with the conventional construction, i.e., the construction in which the edge of the mounting portion on the second lead side is located closer to the semiconductor laser element side than the ends of the second leads on the semiconductor laser element side in the optical axis direction of laser light, the dimension in the optical axis direction of the mounting portion 10 can remarkably be increased, and the dimension in the optical axis direction of the semiconductor laser element 1 can remarkably be increased. Therefore, the cavity length of the semiconductor laser element can be made greater than 1500 μm, and the load of laser oscillation can be reduced, allowing the output of laser light to be increased.

Moreover, according to the semiconductor laser device of the first embodiment, a semiconductor laser element of a long cavity length can be mounted changing neither the outside shape nor the outside dimensions of the package in comparison with the semiconductor laser device of the prior art example shown in FIG. 12. That is, since the outside shape of the package and the outside dimensions of the package need not be changed, no new facility is needed for mass production, and the semiconductor laser device can be mounted on a pickup by the same method as the conventional method.

Moreover, according to the semiconductor laser device of the first embodiment, since the portion of the first lead 2 covered with the resin member 5 has the bent portion 20, meaning that the first lead 2 is not wholly located in an identical plane, the first lead 2 becomes hard to easily fall off the resin member 5 (resin molded portion). Likewise, since the portions of the second leads 3 covered with the resin member 5 also have the bent portions 50 and are not straight, the second leads 3 become hard to easily fall off the resin member 5 (resin molded portion). In other words, the first lead 2 and second leads 3, which have the key-like shapes, do not easily fall off the resin member 5 made of an insulating material.

### The Second Embodiment

FIG. 8 is a plan view of the semiconductor laser device of the second embodiment of the present invention.

The semiconductor laser device of the second embodiment differs from the semiconductor laser device of the first embodiment in that a resin cap portion 60 is provided as a lid portion.

In the semiconductor laser device of the second embodiment, the same constituent elements as those of the semiconductor laser device of the first embodiment are denoted by same reference numerals, and no description is provided for them. Moreover, in the semiconductor laser device of the second embodiment, no description is provided for operational effects common to those of the semiconductor laser device of the first embodiment, and only the operational effects different from those of the semiconductor laser device of the first embodiment are described.

As shown in FIG. 8, in the second embodiment, the resin cap portion 60 is placed so as to oppose to the mounting portion in the normal direction of the mounting surface of the semiconductor laser element on the mounting portion with interposition of a space. The resin cap portion 60 is made of a resin that is an insulating material.

According to the semiconductor laser device of the second embodiment, since the resin cap portion 60 that plays the role of a protecting plate is attached to the frame package, the semiconductor laser element can be protected.

### The Third Embodiment

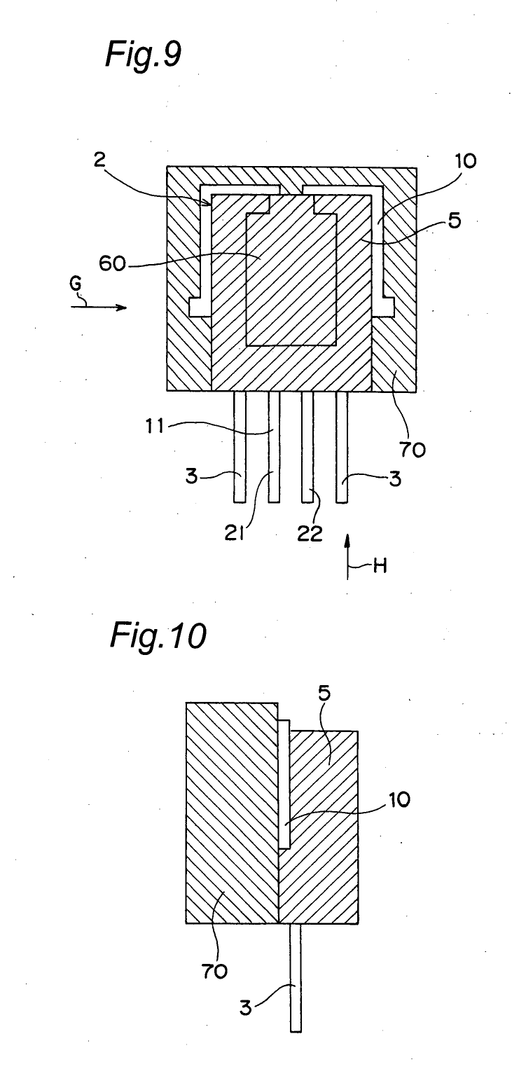

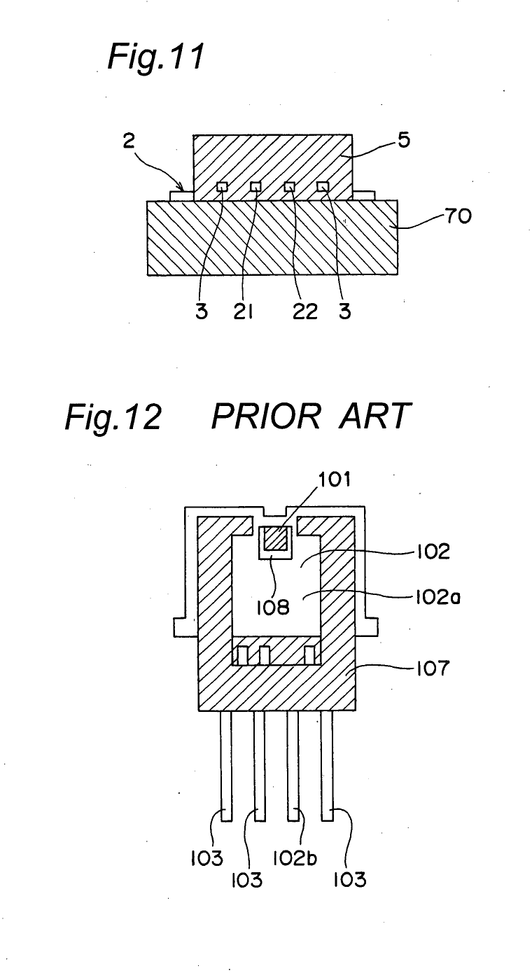

FIG. 9 is a plan view of the semiconductor laser device of the third embodiment of the present invention. FIG. 10 is a side view when the semiconductor laser device of FIG. 9 is viewed from a direction indicated by arrow G in FIG. 9, and FIG. 11 is a front view when FIG. 9 is viewed from a direction indicated by arrow H in FIG. 9.

The semiconductor laser device of the third embodiment differs from the semiconductor laser device of the second embodiment only in that a heat radiation member 70 is provided.

In the semiconductor laser device of the third embodiment, the same constituent elements as those of the semiconductor laser devices of the first and second embodiments are denoted by same reference numerals, and no description is provided for them. Moreover, in the semiconductor laser device of the third embodiment, no description is provided for the operational effects common to those of the semiconductor laser devices of the first and second embodiments, and only the operational effects different from those of the semiconductor laser devices of the first and second embodiments are described.

As shown in FIGS. 10 and 11, in the frame package owned by the semiconductor laser device of the third embodiment, the back surface of the mounting portion 10 is exposed. The heat radiation member (heat radiation block) 70 is adhesively attached to the back surface of the mounting portion 10. The heat radiation member 70 has a thermal conductivity greater than the thermal conductivity of the mounting portion 10. That is, a portion of projection of the semiconductor laser element with respect to the normal direction of the back surface opposite from the semiconductor laser element side of the mounting portion 10 is exposed, and the heat radiation member 70 that has the thermal conductivity of not smaller than the thermal conductivity of the mounting portion that has a prescribed thermal conductivity is put in contact with the portion of projection. When the heat radiation member 70 having a thermal conductivity not smaller than the thermal conductivity of the mounting portion that has the prescribed thermal conductivity is adhesively attached to the portion of projection as in the third embodiment, heat generated in the semiconductor laser element can efficiently be radiated. Although the heat radiation member 70 has been placed on the semiconductor laser device that has the resin cap 60 in the third embodiment, it is, of course, acceptable to place the heat radiation member on the semiconductor laser device that does not have the resin cap described in the first embodiment.

Although the portions 3a, 3a of the second leads 3, 3 have been located on both sides in the direction perpendicular to the optical axis direction of laser light emitted from the semiconductor laser element 1 with regard to part of the mounting portion 10 that connects to the lead portion 11 of the first lead 2 in the above embodiments, it is acceptable to place the second leads only on one side in the direction perpendicular to the optical axis direction of laser light emitted from the semiconductor laser element 1 with regard to part of the mounting portion 10.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device comprising:
a semiconductor laser element;
a first lead having a mounting portion on which the semiconductor laser element is mounted via a submount member and a lead portion that extends in connection to the mounting portion;
at least one second lead; and
a retention member that integrally retains the first lead and the second lead in a state in which the first lead and the second lead are not electrically connected with each other and is made of an insulating material, wherein
the mounting portion has a portion that overlaps the second lead when viewed in plan in a direction perpendicular to an optical axis direction of laser light emitted from the semiconductor laser element.

2. The semiconductor laser device as claimed in claim 1, wherein
a mounting surface in the mounting portion for the semiconductor laser element comprises:
a first portion of a generally rectangular shape; and
a second portion that connects to the first portion in the optical axis direction and whose maximum dimension in a direction perpendicular to the optical axis direction is smaller than a dimension in a widthwise direction of the first portion, and
the second portion has a portion that overlaps the second lead when viewed in plan from the direction perpendicular to the optical axis direction and has a portion put in contact with the submount member.

3. The semiconductor laser device as claimed in claim 1, wherein
the lead portion of the first lead has a first portion and a second portion that extends generally parallel to the first portion.

4. The semiconductor laser device as claimed in claim 1, wherein
each of the first lead and the second lead penetrates the retention member, and
the portion that penetrates the retention member of at least one of the first lead and the second leads has a bent portion.

5. The semiconductor laser device as claimed in claim 3, wherein
the lead portion of the first lead has a first surface portion that connects to a mounting surface of the mounting portion on which the semiconductor laser element is mounted and that has a normal line which is not parallel to a normal line of the mounting surface.

6. The semiconductor laser device as claimed in claim 5, wherein
a surface of the lead portion of the first lead on the semiconductor laser element side has a second surface portion located in a plane identical to a surface of the second lead on the semiconductor laser element side.

7. The semiconductor laser device as claimed in claim 5, wherein
the first surface portion is covered with the retention member.

8. The semiconductor laser device as claimed in claim 2, wherein
the maximum dimension of the second portion in the direction perpendicular to the optical axis direction is not smaller than 800 μm.

9. The semiconductor laser device as claimed in claim 1, comprising:
a lid portion that is placed spaced apart from the mounting portion in a normal direction of a mounting surface on which the semiconductor laser element is mounted in the mounting portion and is made of an insulating material.

10. The semiconductor laser device as claimed in claim 1, wherein
a portion of projection of the semiconductor laser element in a surface opposite from the semiconductor laser element side of the mounting portion with respect to a normal direction of the surface opposite from the semiconductor laser element side of the mounting portion is exposed, and
a heat radiation member having a thermal conductivity of not smaller than a prescribed thermal conductivity is put in contact with the portion of projection.

11. A semiconductor laser device comprising:
a semiconductor laser element;
a first lead having a mounting portion on which the semiconductor laser element is mounted via a submount member and a lead portion that extends in connection to the mounting portion;
at least one second lead; and
a retention member that integrally retains the first lead and the second lead in a mutually insulated state and is made of an insulating material, wherein
a part of the second lead is located at least on one side in a direction perpendicular to an optical axis direction of laser light emitted from the semiconductor laser element with regard to a part of the mounting portion that connects to the lead portion of the first lead.

12. The semiconductor laser device as claimed in claim 11, wherein
the mounting portion comprises:
a first portion of a generally rectangular shape; and
a second portion that connects to the first portion in the optical axis direction and whose maximum dimension in the direction perpendicular to the optical axis direction is smaller than a dimension in a widthwise direction of the first portion, wherein
a part of the second lead is located at least on one side of the second portion, and
the second portion has a portion put in contact with the submount member.
